(19) United States
(12) Patent Application Publication
(10) Pub. No.: US 2015/0343969 A1
(43) Pub. Date: Dec. 3, 2015

(54) VEHICLE POWER SUPPLY CONTROL DEVICE

(71) Applicant: YAZAKI CORPORATION, Tokyo (JP)

(72) Inventors: Yoshihide NAKAMURA, Shizuoka (JP); Akinori MARUYAMA, Shizuoka (JP); Keisuke UETA, Shizuoka (JP)

(73) Assignee: YAZAKI CORPORATION, Tokyo (JP)

(21) Appl. No.: 14/823,111

(22) Filed: Aug. 11, 2015

Related U.S. Application Data
(63) Continuation of application No. PCT/JP2013/084610, filed on Dec. 25, 2013.

(30) Foreign Application Priority Data
Feb. 18, 2013 (JP) 2013-028822

(51) Int. Cl. B60R 16/03; G01R 21/06; G01R 21/133; B60Q 1/14

(52) U.S. Cl. CPC B60R 16/03; B60Q 1/1415; G01R 21/06; G01R 21/1331

(57) ABSTRACT

A power supply control device detects current that actually flowed through each load and a duty ratio of the current using a current detection unit and a duty ratio detection unit, and calculates an actual supply power value of each load using a power data calculation unit. A PWM control duty ratio is calculated by a duty ratio correction value calculation unit such that the calculated actual supply power value corresponds to a target power value of each load and it is set as the duty ratio of the PWM control by a PWM duty ratio control unit. Thus, even if resistance characteristics of each load or a wire harness connected to each load are varied by changes over time or environment, the PWM control duty ratio can be corrected according to the varied resistance characteristics, and power of the target power value is supplied to the load.

### CROSS REFERENCE TO RELATED APPLICATIONS

This application is a continuation of International Application No. PCT/JP2013/084610, filed Dec. 25, 2013, and based upon and claims the benefit of priority from Japanese Patent Application No. 2013-028822, filed Feb. 18, 2013, the entire contents of all of which are incorporated herein by reference.

### TECHNICAL FIELD

This application relates to a power supply control device that controls ON-OFF of semiconductor switching elements interposed between a power supply and loads of a vehicle so as to control supplying power from the power supply to the loads.

### BACKGROUND

In a vehicle, it has been traditionally implemented to control supplying power from a power supply to loads by PWM control of semiconductor switching elements. Among them, there is also a proposal to control supplying power to left and right headlights of a vehicle by PWM control of different duty ratios in accordance with a difference in route resistances due to a difference in respective harness route lengths.

In this proposal, it is aimed to realize lighting of each headlight with the same intensity even when harness route lengths to the left and right headlights are different (refer to JP 2010-537873 A).

### SUMMARY

Incidentally, it is not the case that route resistances of left and right headlights become permanently constant values respectively; for example, they change due to the changes in surrounding environment of the headlights, changes in the harnesses and headlights themselves over time and the like. Therefore, even if duty ratios of the PWM control at the time of supplying power to the left and right headlights are individually set in accordance with the harness route lengths to the respective headlights, there is a possibility that the left and right headlights may not be lit with the same intensity as a result.

The present application was made in the light of the above circumstances, and an object of the present application is to provide a power supply control device that can maintain supplying power to respective loads to be the same even if resistance characteristics of a part of the loads dynamically change among the loads having the same supplied power when power from a power supply is respectively supplied to a plurality of loads of a vehicle using PWM control.

In order to achieve the above-described object, a power supply control device according to an aspect of the present application is a power supply control device for controlling power supplied from a power supply to loads of a vehicle per unit time by PWM control, and includes: a power data calculation unit that is configured to calculate an actual supply power value of each of the loads per unit time from a current value that flowed through each of the loads and its duty ratio and a voltage of the power supply for each of the loads of the vehicle respectively; a duty ratio correction value calculation unit that is configured to calculate a duty ratio of the PWM control to match the actual supply power value with a target power value supplied from the power supply to each of the load per unit time by the PWM control for each load respectively; and a duty ratio control unit that is configured to correct the duty ratio of the PWM control to the duty ratio determined by a duty ratio determination unit for each load respectively.

According to the power supply control device according to the aspect of the present application, the duty ratio of the PWM control is set such that the actual supply power value per unit time of the power that is actually supplied from the power supply to each of the loads by PWM control coincides with a target power value supplied to each of the loads per unit time.

Therefore, even if there exists a load that changes its resistance characteristics or resistance characteristics of a harness connected to the load due to changes over time or changes in the environment among the loads that are supplied power by PWM control, it is possible to maintain a state in which power of the target power value per unit time is supplied to all of the loads respectively by correcting the duty ratio of the PWM control according to the changed resistance characteristics.

Therefore, for example, when power from the power supply is supplied respectively to the loads of the vehicle with the same target power value per unit time using PWM control, even if resistance characteristics of a part of the loads dynamically change, the supplied power amount to each of the loads can be maintained to be the same power amount.

Further, it is possible to individually determine the correction content of the duty ratio in PWM control of each load by the comparison of the actual supply power value of each load with the target power value. Therefore, compared to a case in which the correction content of the duty ratio is determined by comparing other loads with the actual supply power value and the like, the correction value of the duty ratio in PWM control of each load can be detected more easily and rapidly.

According to the power supply control device according to the aspect of the present application, when power from the power supply is supplied respectively to the loads of the vehicle using PWM control, even if resistance characteristics of a part of the loads dynamically change among the loads having the same supplied power amount, the supplied power amount to each of the loads can be maintained to be the same power amount.

### BRIEF DESCRIPTION OF DRAWINGS

FIG. 1 is a circuit diagram illustrating a principle configuration of a power supply control device according to an embodiment.

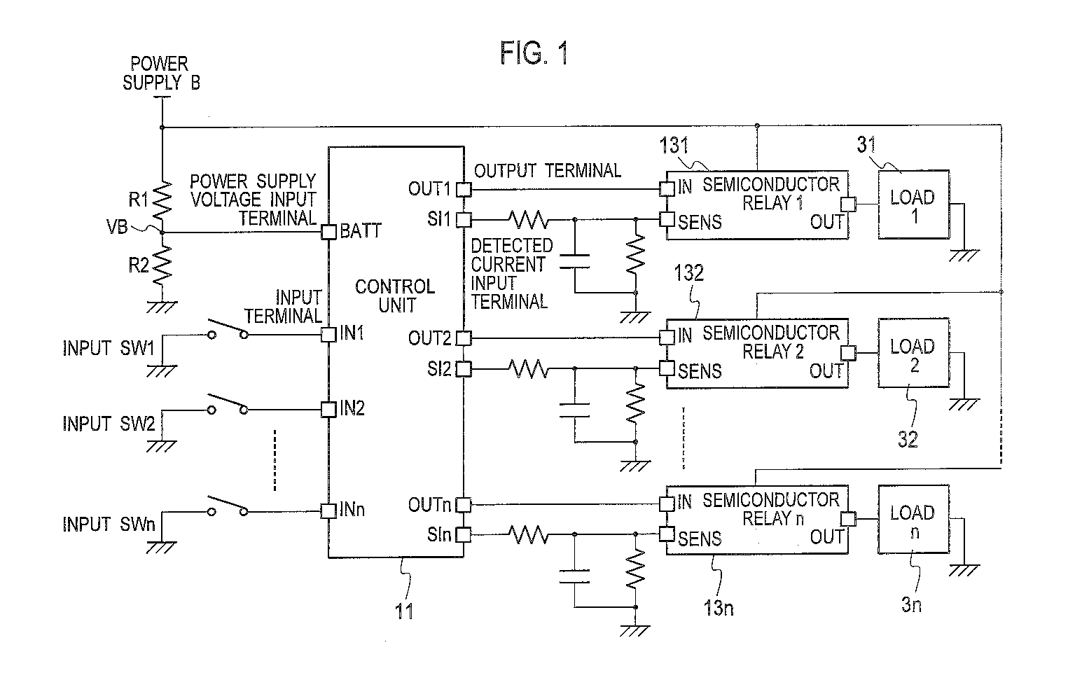

FIG. 2 is a functional block diagram schematically illustrating processing executed at a control unit of FIG. 1.

FIG. 3 is a timing chart illustrating a process when a current detection unit and a duty ratio detection unit of FIG. 2 detect the current passing a load and its duty ratio.

FIG. 4 is a flowchart illustrating operations performed at each load respectively in the power supply control device of FIG. 1.

### DESCRIPTION OF EMBODIMENTS

Hereinafter, an embodiment of the present application will be explained by referring to the drawings.

Based on ON-OFF operations of input switches SW1-SWn mounted on a vehicle (not illustrated), a power supply control device 1 according to the embodiment controls supplying power from a power supply B of the vehicle to loads 31-3n by turning on and off semiconductor relays 131-13n.

In the embodiment, each load 31-3n is connected to a corresponding semiconductor relay 131-13n by a wire harness (not illustrated), and for example is an electric component such as a headlight or the like.

A control unit 11 is composed of a microcomputer, custom IC or the like that realizes various processing by program execution. The control unit 11 has a power supply voltage input terminal BATT, input terminals IN1-INn, output terminals OUT1-OUTn, and detected current input terminals SI1-SIn.

The power supply voltage input terminal BATT is a terminal for monitoring a voltage of the power supply B. A voltage value VB in which the power supply voltage is divided by voltage dividing resistors R1 and R2 is inputted to the power supply voltage input terminal BATT. The input terminals IN1-INn are terminals for monitoring the ON-OFF state of input switches SW1-SWn, and switch signals S1-Sn according to the ON-OFF state of the respective input switches SW1-SWn are inputted.

The output terminals OUT1-OUTn respectively output drive signals DR1-DRn for ON-OFF driving of the semiconductor relays 131-13n when the switch signals S1-Sn of the corresponding input terminals IN1-INn are in the ON state. Current detection signals Il-In from the semiconductor relays 131-13n are inputted respectively to the detected current input terminals SI1-SIn.

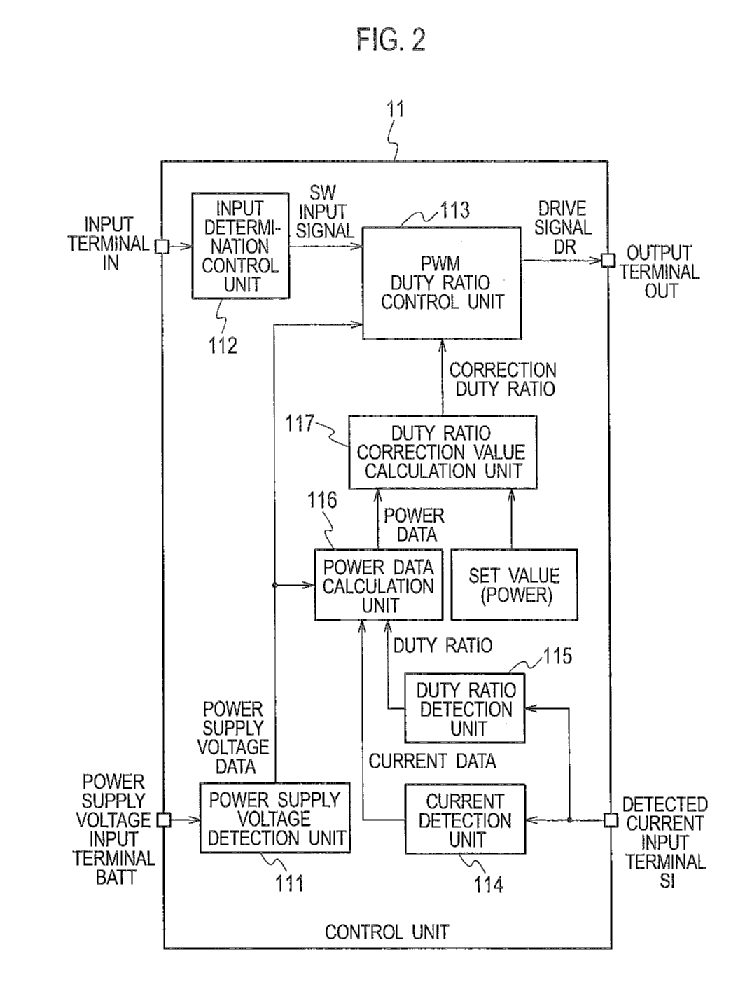

FIG. 2 is a block diagram schematically illustrating processing executed within the control unit 11 based on signals of each terminal of the control unit 11.

Moreover, the control unit 11 executes the same processing respectively independently for each load 31-3n. Thus, in FIG. 2, the processing executed by the control unit 11 is generally illustrated with respect to one load 31 (32 to 3n). Therefore, in FIG. 2, terminals and input/output signals other than the power supply voltage input terminal BATT are illustrated by omitting the branch numbers 1-n.

The control unit 11 realizes each function of a power supply voltage detection unit 111, an input determination control unit 112, a PWM duty ratio control unit 113, a current detection unit 114, a duty ratio detection unit 115, a power data calculation unit 116, and a duty ratio correction value calculation unit 117 by executing a program stored in a memory (not illustrated).

The power supply voltage detection unit 111 detects a terminal voltage of the power supply B (hereinafter referred to as a “power supply voltage”) from the voltage value VB inputted to the power supply voltage input terminal BATT and a division ratio of the voltage dividing resistors R1 and R2, and outputs a power supply voltage data signal indicating the detected power supply voltage value. The input determination control unit 112 determines the ON-OFF state of the input switch SW based on the switch signal S inputted to the input terminal IN, and outputs an SW input signal at an ON state of the input switch SW.

The PWM duty ratio control unit 113 outputs a drive signal DR to the output terminal OUT while the SW input signal from the input determination control unit 112 is being inputted. The duty ratio of the drive signal DR is made to be an initial value right after the input switch SW is turned on, and thereafter, it is corrected to a duty ratio correction value calculated by the duty ratio correction value calculation unit 117.

When the power supply voltage that the power supply voltage data signal indicates exceeds a reference voltage value Vref, the initial value of the duty ratio of the drive signal DR is set to be a value X² which is obtained by squaring a value X (0<X<100) obtained by dividing the reference voltage value Vref by the power supply voltage. For example, when the power supply voltage that the power supply voltage data signal indicates is 15V and the reference voltage value Vref is 13.5V, the initial value of the duty ratio of the drive signal DR is (13.5/15)²=0.81, and thus, it is 81%.

This initial value X² is a duty ratio suitable to make the power value per unit time that the power supply B supplies to the load 3 to a target power value. The target power value is set for each load 3, and for example can be stored in a memory of the control unit 11.

Further, when the power supply voltage that the power supply voltage data signal indicates does not exceed the reference voltage value Vref, the initial value of the duty ratio of the drive signal DR is set to be 100% (DC drive).

From the current detection signal I inputted to the detected current input terminal SI, the current detection unit 114 and the duty ratio detection unit 115 respectively detect a passing current of the load 3 (a current value that has passed through the load 3) and its duty ratio that a current sensor circuit (not illustrated) within the semiconductor relay 13 detects, and output a current data signal and a duty ratio signal indicating the detection result respectively.

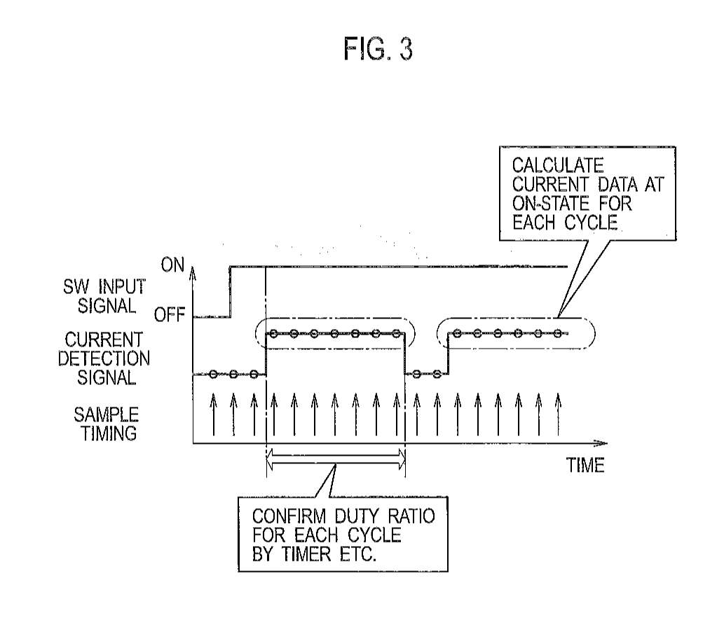

FIG. 3 is a timing chart illustrating a process of when the current detection unit 114 and the duty ratio detection unit 115 detect the passing current of the load 3 and its duty ratio. When the SW input signal from the input determination control unit 112 as illustrated in the upper stage of FIG. 3 is switched from OFF to ON, power from the power supply B is supplied to the load 3 via the semiconductor relay 13 which is ON-OFF driven by PWM control by the drive signal DR.

Then, as illustrated in the middle stage of FIG. 3, the current detection signal I according to the current that passes through the load 3 detected by the current sensor circuit of the semiconductor relay 13 is inputted to the detected current input terminal SI. The current detection unit 114 and the duty ratio detection unit 115 sample the current detection signal I of the detected current input terminal SI at the sample timing as illustrated in the lower stage of FIG. 3.

The current detection unit 114 detects an average value of each sampling value of a continuous section (ON section) from the rise to the fall of the current detection signal I whose level is not zero as the passing current of the load 3 (current value that has passed through the load). The duty ratio detection unit 115 identifies the ON section and the OFF section of the passing current of the load 3 of the current detection signal I from the timing of rise and fall of the current detection signal I, and detects the ON-OFF duty ratio of the passing current of the load 3 from the identified ON section and OFF section.

Moreover, the duty ratio detection unit 115 may detect a duty ratio of the drive signal DR that the PWM duty ratio control unit 113 sets as the ON-OFF duty ratio of the passing current of the load 3 also.

The power data calculation unit 116 calculates an actual power value supplied to the load 3 per unit time (actual supplied power value=effective value) from the power supply voltage data signal from the power supply voltage detection unit 111, and the current data signal and duty ratio signal from the current detection unit 114 and the duty ratio detection unit 115.

Specifically, the power data calculation unit 116 obtains a current time product by multiplying the passing current of the load 3 (current value that has passed through the load) by its duty ratio which the current data signal and the duty ratio signal indicate, and multiplies this by the power supply voltage which the power supply voltage data signal indicates so as to calculate the actual supply power value per unit time. The power data calculation unit 116 then outputs the power data signal indicating the calculated actual supply power value.

For example, when the passing current of the load 3 is 5.85 A, its duty ratio is 79%, and the power supply voltage is 15 V, the actual supply power value (power data) becomes 15 V×5.85 A×79%=approximately 69.3 W.

The duty ratio correction value calculation unit 117 calculates a duty ratio correction value of the drive signal DR (duty ratio correction value of the PWM control), and outputs a correction duty ratio signal indicating the calculated correction value.

The duty ratio correction value of the drive signal DR is to match the actual supply power value per unit time of the load 3 indicated by the power data signal from the power data calculation unit 116 with the above-described target power value (set value) of the supply power per unit time corresponding to the load 3.

For example, when the load 3 is a bulb of the normal rated power of 60 W, current that flows through the load 3 when the rated voltage of 12 V is applied is 5 A. Therefore, when the reference voltage value of Vref=13.5 V is applied to the load 3, current that flows through the load 3 generally becomes 5 A×(13.5 V/12 V)^{1/2}=approximately 5.3 A if the route resistance and the like is ignored. Therefore, the target power value (set value) of this load 3 becomes 13.5 V×5.3 A=approximately 71.6 W.

Thus, if the actual supply power value of the load 3 was 69.3 W as in the above-described calculation result, since the power supply voltage is 15 V which exceeds the reference voltage value Vref (=13.5 V), the duty ratio correction value of the drive signal DR is calculated such that the actual supply power value which was 69.3 W is risen to 71.6 W which is the target power value.

The duty ratio correction value in this case can be calculated by dividing the target power value (set value) per unit time by the actual supply power value of the load 3 per unit time (15 V×5.85 A=87.75 W) in a case that the load 3 is DC driven by the power supply voltage (71.6 W/87.75 W) (duty ratio correction value=approximately 82%).

The PWM duty ratio control unit 113 corrects the duty ratio of the drive signal DR that it outputs to the output terminal OUT to the duty ratio correction value of the drive signal DR indicated by the correction duty ratio signal when the correction duty ratio signal from the duty ratio correction value calculation unit 117 is inputted while the drive signal DR is outputted to the output terminal OUT.

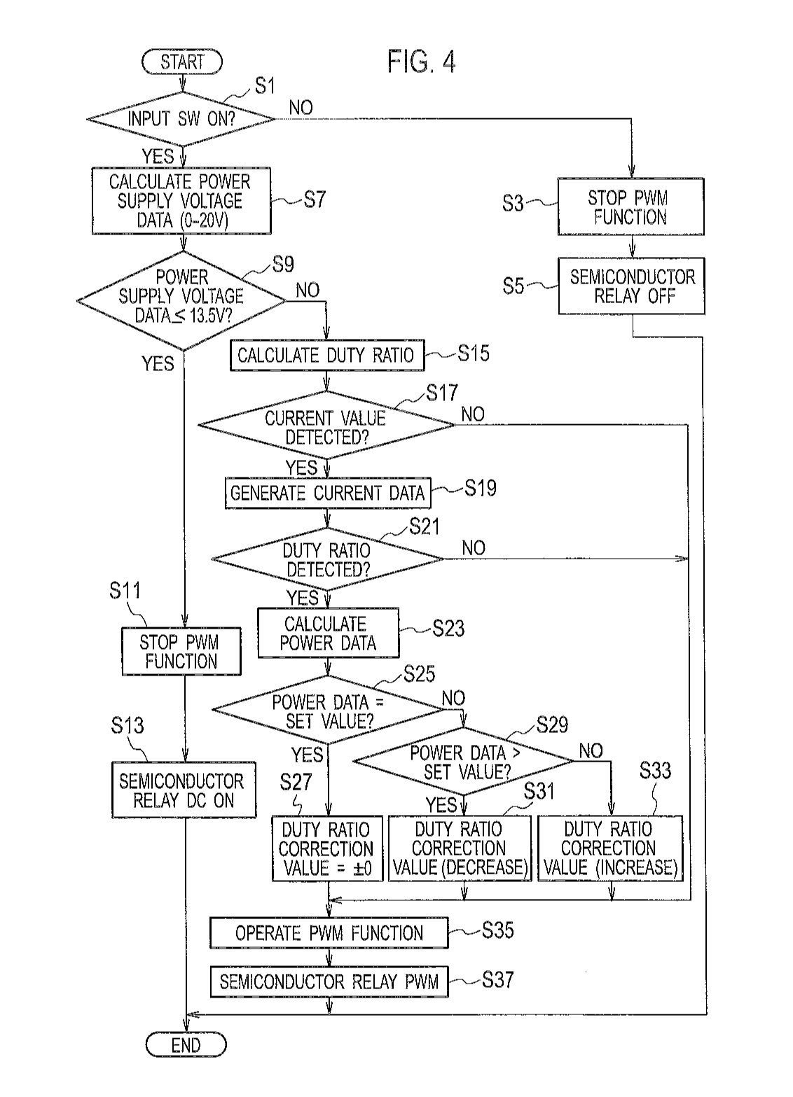

Next, operations (processes) performed at each load 3 in the power supply control device 1 respectively will be explained by referring to the flowchart of FIG. 4. In the power supply control device 1, operations as illustrated in the flowchart of FIG. 4 are repeated in each fixed cycle.

First, from a signal level of the switch signal S, it is confirmed whether or not the input switch SW is turned ON (step S1). When the input switch SW is not turned ON (NO at step 51), a function of PWM control for supplying power to the load 3 is stopped (step S3), and the output of the drive signal DR is stopped so as to turn off the semiconductor relay 13 (step S5), and a series of operations is terminated.

On the other hand, when the input switch SW is turned ON (YES at step S1), the power supply voltage detection unit 111 detects the power supply voltage (0-20 V) (step S7). The detected power supply voltage is notified to the PWM duty ratio control unit 113 and the power data calculation unit 116 by means of the power supply voltage data signal.

Subsequently, it is confirmed whether or not the power supply voltage does not exceed the reference voltage value Vref (step S9). Here, the reference voltage value Vref is assumed to be 13.5 V. When the power supply voltage is not exceeding the reference voltage value Vref (=13.5 V) (YES at step S9), a function of PWM control for supplying power to the load 3 is stopped (step S11), and the drive signal DR with the duty ratio of 100% is outputted to DC drive the semiconductor relay 13 (step S13), and thereafter, a series of operations is terminated.

On the other hand, when the power supply voltage is exceeding the reference voltage value Vref (NO at step S9), the PWM duty ratio control unit 113 calculates the initial value of the duty ratio of the drive signal DR (calculates the duty ratio) (step S15). Then, it is confirmed whether or not the current detection unit 114 has detected an ON section of the current detection signal I (whether a power supply value could be detected) (step S17).

When the ON section of the current detection signal I is not detected (NO at step S17), the process proceeds to step S35. Moreover, when the ON section of the current detection signal I is detected (YES at step S17), the passing current of the load 3 is detected by the current detection unit 114, and the current data signal is generated (step S19).

Subsequently, it is confirmed whether or not the duty ratio detection unit 115 has detected the duty ratio of the current detection signal I (whether the duty ratio could be detected) (step S21). When the duty ratio of the current detection signal I has not been detected (NO at step S21), the process proceeds to step S35. Moreover, when the duty ratio of the current detection signal I has been detected (YES at step S21), the power data calculation unit 116 calculates the power data indicating the actual supply power value per unit time of the load 3 (step S23).

Then it is confirmed whether or not the actual supply power value per unit time that the calculated power data (the actual supply power value of the load 3) indicates is equal to the target power value (set value) of the supplied power per unit time for the load 3 (step S25). When it is equal (YES at step S25), the duty ratio that is the same as the current duty ratio calculated at the duty ratio correction value calculation unit 117 is set as the duty ratio after the correction by the PWM duty ratio control unit 113 (step S27) and the process proceeds to step S35.

When the actual supply power value (power data) is not equal to the target power value (set value) (NO at step S25), it is confirmed whether or not the actual supply power value (power data) exceeds the target power value (set value) (step S29). When it exceeds (YES at step S29), the duty ratio decreased in value from the current value calculated by the duty ratio correction value calculation unit 117 is set as the corrected duty ratio by the PWM duty ratio control unit 113 (step S31) and thereafter the process proceeds to step S35.

Moreover, when the actual supply power value (power data) does not exceed the target power value (set value) (NO at step S29), the duty ratio increased in value from the current value calculated by the duty ratio correction value calculation unit 117 is set as the corrected duty ratio by the PWM duty ratio control unit 113 (step S33) and thereafter the process proceeds to step S35.

It should be noted that the duty ratio value after the correction which is set at step S31 and step S33 can be determined by the above-described procedures.

At step S35, supplying power to the load 3 is PWM controlled, and the drive signal DR of the duty ratio set by one of step S15, step S27, step S31, or step S33 is outputted to PWM-control drive the semiconductor relay 13 (step S37), and thereafter, a series of operations is terminated.

In the power supply control device 1 according to the embodiment, the duty ratio of the PWM control is set by the PWM duty ratio control unit 113 such that the actual supply power value of the load 3 obtained from the current value that actually flowed through each load 3 and its duty ratio coincides with the target power value for the load 3.

Therefore, even if there exists a load 3 that changes its resistance characteristics or resistance characteristics of a wire harness (not illustrated) connected to the load 3 due to changes over time or changes in the environment among the plurality of loads 3 (31-3n) that are supplied power by PWM control, it is possible to maintain a state in which power of the target power value per unit time is supplied to all of the loads 3 (31-3n) respectively by correcting the duty ratio of the PWM control according to the changed resistance characteristics.

Therefore, for example, when power from the power supply B is supplied respectively to a plurality of loads 3 (31-3n) of a vehicle with the same target power value per unit time using PWM control, even if resistance characteristics of a part of the loads 3 (31-3n) dynamically changes, the supplied power amount to each of the loads 3 (31-3n) can be maintained to be the same power amount.

For example, in a case that the loads 3 are left and right headlights of a vehicle, by performing the above-described control individually, the power supplied to each headlight can be made the same even if there is a difference in dynamic resistance characteristic changes such as changes over time or changes in the environment that occur individually in respective harnesses from the power supply B to the respective headlights. Therefore, brightness of the left and right headlights can be made to match precisely without unevenness.

Further, in the power supply control device 1 according to the embodiment, it is possible to individually determine the correction content of the duty ratio in PWM control of each load 3 (31-3n) by the comparison of the actual supply power value of each load 3 (31-3n) with the target power value. Therefore, compared to a case in which the correction content of the duty ratio is determined by comparing other loads 3 (31-3n) with the actual supply power value and the like, the correction value of the duty ratio in PWM control of each load 3 (31-3n) can be detected more easily and rapidly.

It should be noted that the semiconductor relay 13 (131-13n) was used in the embodiment, but the present application is applicable also in a case of PWM controlling the power supply to the loads 3 (31-3n) using a semiconductor switching element other than the semiconductor relay 13, such as a power semiconductor switch and the like.

What is claimed is:

1. A power supply control device for controlling power supplied from a power supply to loads of a vehicle per unit time by PWM control, comprising:
a power data calculation unit that is configured to calculate an actual supply power value of each of the loads per the unit time from a current value that flowed through each of the loads and its duty ratio and a voltage of the power supply for each of the loads of the vehicle respectively;
a duty ratio correction value calculation unit that is configured to calculate a duty ratio of the PWM control to match the actual supply power value with a target power value supplied from the power supply to each of the loads per unit time by the PWM control for each load respectively; and
a duty ratio control unit that is configured to correct the duty ratio of the PWM control to the duty ratio calculated by the duty ratio correction value calculation unit for each load respectively.
